(19) United States
(12) Patent Application Publication
(10) Pub. No.: US 2026/0239964 A1
(43) Pub. Date: Aug. 13, 2026

(54) ELECTRONIC DEVICE

(71) Applicants: Innolux Corporation, Miaoli County (TW); nD-HI Technologies Lab, Inc., Taipei City (TW)

(72) Inventors: Ho-Ming Tong, Taipei City (TW); Chun-Yu Chien, Miaoli County (TW); Chih-Chao Chuang, Miaoli County (TW); Ching-Yu Chu, Miaoli County (TW); Shu-Hsien Wu, Miaoli County (TW)

(73) Assignees: Innolux Corporation, Miaoli County (TW); nD-HI Technologies Lab, Inc., Taipei City (TW)

(21) Appl. No.: 19/433,898

(22) Filed: Dec. 28, 2025

Related U.S. Application Data
(60) Provisional application No. 63/748,992, filed on Jan. 24, 2025.

(30) Foreign Application Priority Data
Sep. 9, 2025 (CN) 202511284449.X

(51) Int. Cl. H10W 40/20; H10W 40/22; H10W 90/00

(52) U.S. Cl. CPC H10W 40/235; H10W 40/226; H10W 40/242; H10W 90/7295

(57) ABSTRACT

An electronic device includes a heat dissipation component, a through hole, a package structure, a heat dissipation cover, and a connecting component. The through hole extends through the heat dissipation component. The package structure is disposed on a first surface of the heat dissipation component, and includes a circuit structure and an electronic unit. The circuit structure includes a metal layer, and a thermal conductivity of the heat dissipation component is different from a thermal conductivity of the metal layer. The electronic unit is disposed on the circuit structure and is electrically connected to the circuit structure. The heat dissipation cover is attached to the package structure. The connecting component electrically connects the circuit structure of the package structure, and extends through the through hole of the heat dissipation component beyond the second surface of the heat dissipation component.

### CROSS-REFERENCE TO RELATED APPLICATION

This application claims the priority benefit of U.S. Provisional Application No. 63/748,992, filed on January 24, 2025 and China Application No. 202511284449.X, filed on September 9, 2025. The entirety of each of the above-mentioned patent applications is hereby incorporated by reference herein and made a part of this specification.

### BACKGROUND

### Technical Field

The present disclosure relates to an electronic device, and particularly relates to an electronic device having improved heat dissipation performance.

### Related Art

Integrating multiple chips or electronic components in the same package is a development trend in packaging technology. The substrate used to carry the package needs to have supporting strength to improve the stability of the packaged product. In addition, when multiple chips or electronic components are integrated in the same package, heat dissipation issues may be encountered. Therefore, developing a substrate that has supporting strength and may provide heat dissipation is an urgent issue that needs to be addressed.

### SUMMARY

The present disclosure is directed to an electronic device that does not use a core package substrate made of organic material and has better heat dissipation performance.

### BRIEF DESCRIPTION OF THE DRAWINGS

FIG. 1 is a cross-sectional schematic diagram of an electronic device according to an embodiment of the present disclosure.

FIG. 2A to FIG. 2D are cross-sectional schematic diagrams of a manufacturing method of an electronic device according to an embodiment of the present disclosure.

FIG. 2E is a cross-sectional schematic diagram of a manufacturing method of an electronic device according to another embodiment of the present disclosure.

FIG. 3A is a partial cross-sectional schematic diagram of a circuit structure of an electronic device according to an embodiment of the present disclosure.

FIG. 3B is a partial cross-sectional schematic diagram of a circuit structure of an electronic device according to another embodiment of the present disclosure.

FIG. 4A is an exploded perspective schematic diagram of an electronic device according to an embodiment of the present disclosure.

FIG. 4B is an exploded perspective schematic diagram of an electronic device according to another embodiment of the present disclosure.

### DESCRIPTION OF THE EMBODIMENTS

The disclosure may be understood through referring to the following detailed description in conjunction with the drawings. It should be noted that in order to facilitate the understanding by the reader and for the conciseness of the drawings, multiple drawings in the disclosure only depict a part of an electronic device, and specific elements in the drawings are not drawn according to actual scale. In addition, the number and the size of each element in the drawings are only for illustration and are not intended to limit the scope of the disclosure.

In the following specification and claims, words such as "containing" and "comprising" are open-ended words, which should be interpreted as "including but not limited to...".

In addition, relative terms such as "below" or "bottom portion" and "above" or "top portion" may be used in the embodiments to describe the relative relationship between an element and another element in the drawings. It should be understood that if a device in the drawings is flipped upside down, elements described as "below" will become elements described as "above".

In some embodiments of the disclosure, terms related to upper, connection, bonding and joining, such as "connected" and "interconnection", unless otherwise defined, may refer to two structures that are directly in contact or may also refer to two structures that are not directly (indirectly) in contact, wherein there is another structure provided between the two structures. Furthermore, the term "coupling" includes the transfer of energy between two structures through means of direct or indirect electrical connection or the transfer of energy between two separate structures by means of mutual induction.

The terms "about", "equal to", "equivalent" or "same", "substantially", or "roughly" are generally interpreted as within 20% of a given value or range, or interpreted as within 10%, 5%, or 0.5% of the given value or range.

In the disclosure, the definition of roughness judgment may be observed by the SEM or the transmission electron microscope (TEM), etc. Under magnification where surface undulations with peak-to-valley distance differences of 0.15 micrometers (μm) to 1μm can be observed, the roughness range is determined by taking a unit length (for example, 10μm) sample to compare the undulation conditions. Here, "appropriate magnification" means that at least one surface may have a roughness (Rz) or an average roughness (Ra) of at least 10 peaks and valleys visible under the field of view of such a magnification.

As used herein, the terms "film" and/or "layer" may refer to any continuous or discontinuous structure and material (for example, a material deposited by a method of the disclosure). The film or the layer may include a material or a layer having pinholes, which may be at least partially continuous.

Although the terms first, second, third... may be used to describe various constituent elements, the constituent elements are not limited by the terms. The terms are only used to distinguish a single constituent element from other constituent elements in the specification. The same terms may not be used in the claims, but replaced according to the order in which the elements are declared in the claims.

An electronic device of the disclosure may include a power module, a semiconductor device, a semiconductor package device, a display device, an antenna device, a sensing device, a light emitting device, or a splicing device. According to an embodiment of the disclosure, a manufacturing method of the electronic device provided may be applied, for example, to a wafer-level package (WLP) process or a panel-level package (PLP) process and may adopt a chip first process or a chip last/RDL first process, which will be further described in detail below. The electronic device referred to in the disclosure may include a system on chip (SoC), a system in package (SiP), an antenna in package (AiP), co-packaged optics (CPO), or a combination of the above, but not limited thereto.

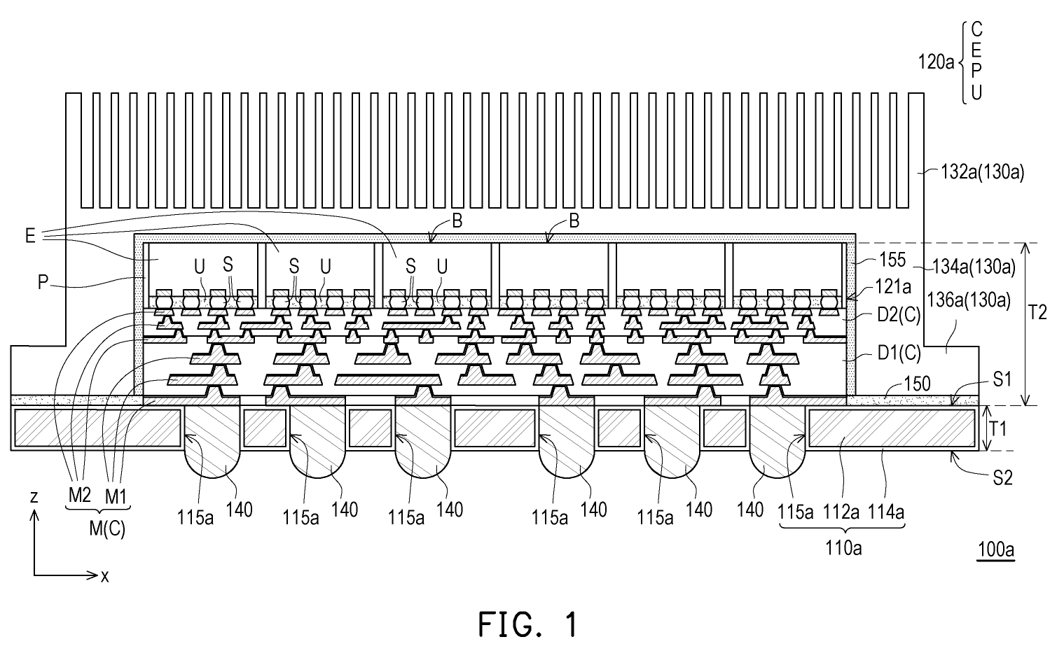

FIG. 1 is a cross-sectional schematic diagram of an electronic device according to an embodiment of the present disclosure. Please refer to FIG. 1 first, in this embodiment, the electronic device 100a includes a heat dissipation component 110a, a through hole 115a, a package structure 120a, a heat dissipation cover 130a, and a connecting component 140. The heat dissipation component 110a has a first surface S1 and a second surface S2 opposite to each other. The through hole 115a penetrates through the heat dissipation component 110a. The package structure 120a is disposed on the first surface S1 of the heat dissipation component 110a and includes a circuit structure C and an electronic unit E. The circuit structure C includes a metal layer M, and a thermal conductivity of the heat dissipation component 110a is different from a thermal conductivity of the metal layer M, or the thermal conductivity of the heat dissipation component 110a is greater than the thermal conductivity of the metal layer M. The electronic unit E is disposed on the circuit structure C and electrically connected to the circuit structure C. The heat dissipation cover 130a is attached to the package structure 120a. The connecting component 140 is electrically connected to the circuit structure C and disposed in the through hole 115a. In some embodiments, the connecting component 140 may extend beyond the second surface S2 of the heat dissipation component 110a through the through hole 115a.

In detail, in this embodiment, the through hole 115a extends from the first surface S1 of the heat dissipation component 110a toward the second surface S2 and penetrates through the heat dissipation component 110a. In one embodiment, the heat dissipation component 110a includes a conductive portion 112a and an insulation portion 114a, wherein the insulation portion 114a covers the conductive portion 112a. In one embodiment, a material of the conductive portion 112a is, for example, Invar alloy, and a material of the insulation portion 114a is, for example, silicon oxide (SiO), silicon nitride (SiN), aluminum nitride (AlN), silicon carbide (SiC), aluminum silicon carbide (AlSiC), or diamond. In one embodiment, a thickness T1 of the heat dissipation component 110ais, for example, 100 micrometers to 2000 micrometers. In one embodiment, a coefficient of thermal expansion (CTE) of the conductive portion 112a may be 0.8*10⁻⁶/K~18*10⁻⁶/K, and a thermal conductivity (TC) of the conductive portion 112a is 12W/m*K~2000W/m*K. In one embodiment, the heat dissipation component 110a may adopt a single material, such as aluminum nitride, silicon carbide, diamond, or any insulating material with high thermal conductivity, which means the heat dissipation component 110a is an insulating support.

The package structure 120a is disposed on the first surface S1 of the heat dissipation component 110a, wherein a dimension of the heat dissipation component 110a is larger than a dimension of the package structure 120a. In a cross-sectional view, the heat dissipation component 110a protrudes outward (such as in the X-axis direction) by a distance around the package structure 120a. The metal layer M of the circuit structure C of the package structure 120a includes a first metal layer M1 and a second metal layer M2, and the first metal layer M1 is located between the second metal layer M2 and the heat dissipation component 110a. In one embodiment, a line width/line spacing (L/S) of the first metal layer M1 may be greater than a line width/line spacing of the second metal layer M2. In one embodiment, the first metal layer M1 and the second metal layer M2 are, for example, traces, conductive through holes, conductive blind holes, pads, or combinations thereof. In one embodiment, a material of the metal layer M may be, for example, copper, titanium, nickel, or combinations or alloys of the aforementioned materials.

Furthermore, the circuit structure C of the package structure 120a further includes a first dielectric layer D1 and a second dielectric layer D2, wherein the first metal layer M1 and the first dielectric layer D1 may define a first redistribution layer (RDL), and the second metal layer M2 and the second dielectric layer D2 may define a second RDL. In one embodiment, the first RDL is, for example, a coarse-pitch RDL, and the second RDL is, for example, a fine-pitch RDL. In one embodiment, the RDL may be electrically connected to, for example, the electronic unit E through solder balls or other bonding components. In one embodiment, the RDL may include at least one dielectric layer and at least one metal layer alternately stacked along direction Z. Through the at least one dielectric layer and the at least one metal layer, circuit redistribution and/or enhancement of circuit fan-out or fan-in area may be achieved, or different electronic units may be electrically connected to each other through the RDL. For example, the pitch of two adjacent contact pads at one end of the RDL contacting the electronic unit may be smaller than or equal to the pitch of two adjacent contact pads at the other end of the RDL away from the electronic unit, therefore the RDL may adjust circuit fan-out conditions or electrically connect a circuit structure/electronic unit having a first pitch to a circuit structure/electronic unit having a second pitch. The method of forming the RDL may include using a dual damascene process, lithography etching process, surface treatment process, laser process, electroplating process, deposition process, combinations of the aforementioned processes, or other processes to form at least one dielectric layer and at least one metal layer. The surface treatment process includes roughening or activating the surface of the dielectric layer or the surface of the metal layer to enhance its adhesion capability, for example, by increasing surface roughness to enhance bonding force with subsequent film layers. It should be noted that only three layers of the first metal layer M1 and three layers of the second metal layer M2 are schematically illustrated herein. In one embodiment, the number of layers of the first metal layer M1 and the number of layers of the second metal layer M2 may be increased or decreased according to requirements. In one embodiment, the number of layers of the first metal layer M1 and the number of layers of the second metal layer M2 may be different. In one embodiment, the metal layer M is, for example, copper, wherein the CTE of copper is 16.8*10⁻⁶/K to 17.9*10⁻⁶/K, and the TC of copper is 400W/m*K. In one embodiment, the material of the first dielectric layer D1 is, for example, photosensitive polyimide (PSPI) or Ajinomoto build-up film (ABF), but is not limited thereto. In one embodiment, a material of the second dielectric layer D2 is, for example, photosensitive polyimide, silicon dioxide (SiO₂), silicon nitride (SiN_{X}), or polymer.

Furthermore, the electronic unit E of the package structure 120a is disposed on the circuit structure C and electrically connected to the circuit structure C. In one embodiment, the electronic unit E includes passive components, active components, or combinations thereof, such as known good die (KGD), diodes, antenna units, sensors, structures of semiconductor-related processes, structures of semiconductor-related processes disposed on substrates (such as polyimide, glass, silicon substrate, or other suitable substrate materials), passive components, filters, transistors, sensors, or microelectromechanical system (MEMS) components. In one embodiment, the electronic unit E is electrically connected to the second metal layer M2 of the circuit structure C through the connecting component S. In one embodiment, a material of the connecting component S may be, for example, copper, nickel, tin, silver, gold, gallium, or combinations thereof. The package structure 120a may further include an adhesive layer U disposed between each electronic unit E and the circuit structure C. In one embodiment, the adhesive layer U may be, for example, an underfill layer that directly contacts the active surface of the electronic unit E and the surface of the outermost second metal layer M2, and fills the space between two adjacent connecting components S. Additionally, the package structure 120a further includes an encapsulant P disposed on the circuit structure C and covering the electronic unit E and the adhesive layer U, wherein a portion of the encapsulant P fills between adjacent adhesive layers U and between adjacent electronic units E. In one embodiment, the encapsulant P exposes a back surface B of the electronic unit E, which facilitates heat dissipation. In one embodiment, a material of the encapsulant P is, for example, an insulating material, which may include a silicon oxide layer, a silicon nitride layer, a silicon oxynitride layer, or a polymer, wherein the encapsulant P is formed by, for example, a deposition process or a molding process, but is not limited thereto. A material of the adhesive layer U is similar to that of the encapsulant P. In one embodiment, a thickness T2 of the package structure 120a is, for example, 1 millimeter to 5 millimeters. The term "covering" described in this disclosure refers to, in a cross-sectional view, component A contacting at least two opposite sides of component B.

Please refer to FIG. 1 again. In this embodiment, the heat dissipation cover 130a includes a heat dissipation fin portion 132a, a side cover portion 134a, and an extension portion 136a. The heat dissipation fin portion 132a is attached to the electronic unit E, the side cover portion 134a connects the heat dissipation fin portion 132a and the extension portion 136a and covers a peripheral surface 121a of the package structure 120a, and the extension portion 136a is attached to the heat dissipation component 110a. In one embodiment, an extension direction of the heat dissipation fin portion 132a is parallel to an extension direction of the extension portion 136a, while an extension direction of the side cover portion 134a is perpendicular to the extension direction of the heat dissipation fin portion 132a. In one embodiment, the heat dissipation fin may be an integrally formed structure. In one embodiment, the shape of the heat dissipation cover 130a is, for example, cap-shaped. In one embodiment, a material of the heat dissipation cover 130a is, for example, metal, alloy, diamond, ceramic, or high thermal conductivity material.

Furthermore, according to some embodiments, the connecting component 140 may directly contact the first metal layer M1 of the circuit structure C and extend through the through hole 115a to outside the second surface S2. That is, the connecting component 140 is located within the through hole 115a, fills the through hole 115a, and extends outside the heat dissipation component 110a. Subsequently, the electronic device 100a may be electrically connected to an external circuit (such as a circuit board) through the connecting component 140. The heat dissipation component 110a may support the connecting component 140 and may prevent the edge of the connecting component 140 from fracturing due to stress.

Additionally, the electronic device 100a of this embodiment further includes a thermal interface material 150, disposed between the heat dissipation component 110a and the extension portion 136a of the heat dissipation cover 130a, wherein the heat dissipation cover 130a contacts and is fixed to the first surface S1 of the heat dissipation component 110a through the thermal interface material 150. Furthermore, the electronic device 100a further includes a thermal interface material 155, disposed between the electronic unit E and the heat dissipation fin portion 132a of the heat dissipation cover 130a as well as between the side cover portion 134a of the heat dissipation cover 130a and the peripheral surface 121a of the package structure 120a, wherein the package structure 120a contacts the heat dissipation cover 130a through the thermal interface material 150 and the thermal interface material 155. In one embodiment, the first metal layer M1 of the circuit structure C may directly contact the thermal interface material 150 and/or the thermal interface material 155. In one embodiment, the second metal layer M2 of the circuit structure C may directly contact the thermal interface material 155. In one embodiment, the metal layer M in contact with the thermal interface material 150 and/or the thermal interface material 155 is a ground layer or a dummy metal layer without circuit function. In one embodiment, the arrangement of the thermal interface material 150 and the thermal interface material 155, in addition to allowing heat to spread horizontally (such as in the XY plane direction)/laterally to enhance heat dissipation effect, may also serve as a buffer layer for the heterogeneous interface between the heat dissipation component 110a/heat dissipation cover 130a and the package structure 120a.

In brief, in this embodiment, the package structure 120a is disposed on the heat dissipation component 110a, and the heat dissipation cover 130a is attached to the package structure 120a, wherein the thermal conductivity of the heat dissipation component 110a is greater than the thermal conductivity of the metal layer M of the circuit structure C. That is, the four sides (i.e., peripheral surface 121a) and the top (i.e., the back surface B of the electronic unit E) of the package structure 120a are all covered by the heat dissipation cover 130a, while the bottom (i.e., the outermost first metal layer M1) of the package structure 120a directly contacts the heat dissipation component 110a, meaning that the package structure 120a is located in the space defined by the heat dissipation cover 130a and the heat dissipation component 110a, and may contact the heat dissipation cover 130a through the thermal interface material 150 and the thermal interface material 155. High-temperature heat may flow downward to the heat dissipation component 110a with high thermal conductivity for active heat dissipation, and may also directly exit from the back surface B of the electronic unit E to the heat dissipation fin portion 132a of the heat dissipation cover 130a, enabling the electronic device 100a of this embodiment to have better heat dissipation effect. This embodiment performs heat dissipation through the arrangement of the heat dissipation component 110a and the heat dissipation cover 130a, thereby avoiding the problem of thermal deformation. Therefore, the electronic device 100a of this embodiment may not only have better heat dissipation performance but also have better structural reliability. Furthermore, the dimension of the heat dissipation component 110a of this embodiment is larger than the dimension of the package structure 120a, which may provide heat dissipation effect or may enhance the structural rigidity of the overall electronic device 100a.

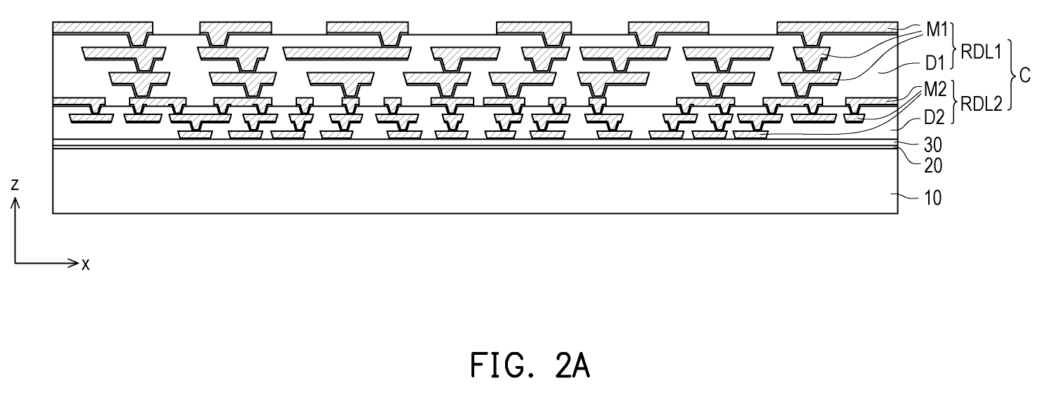

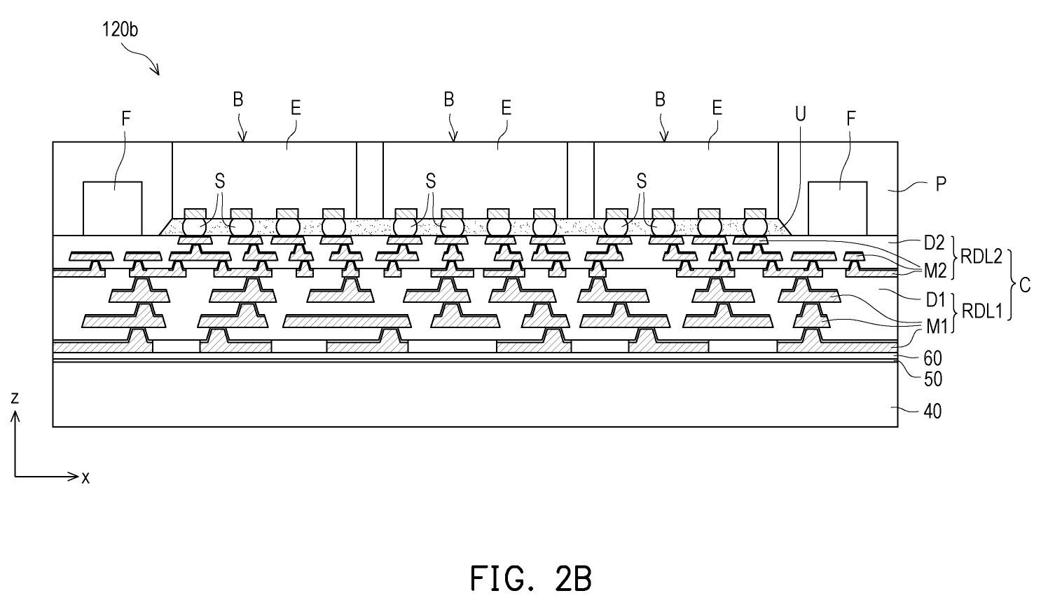

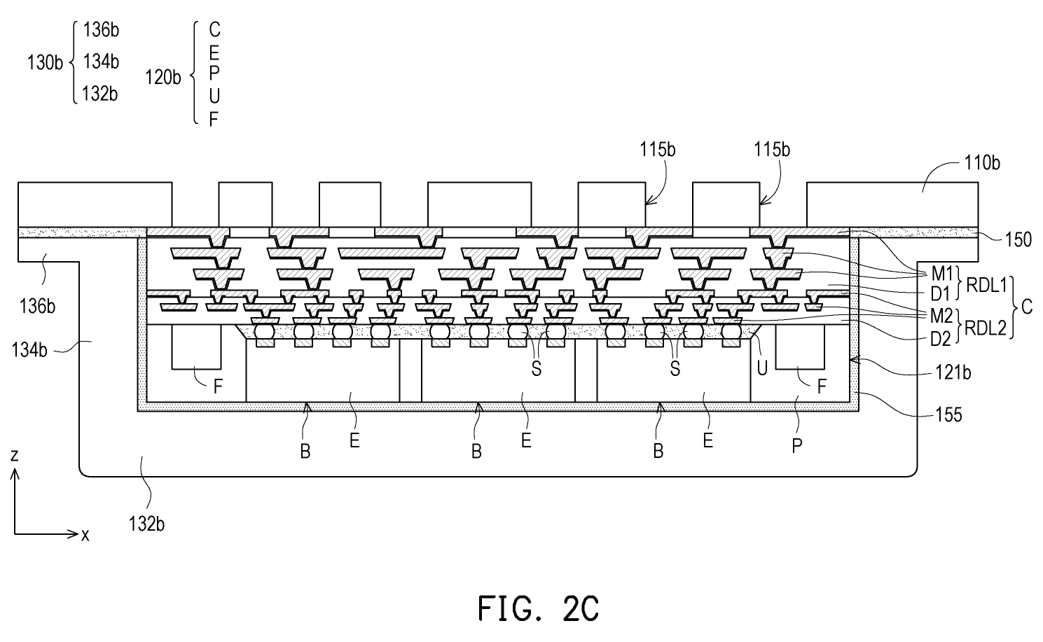

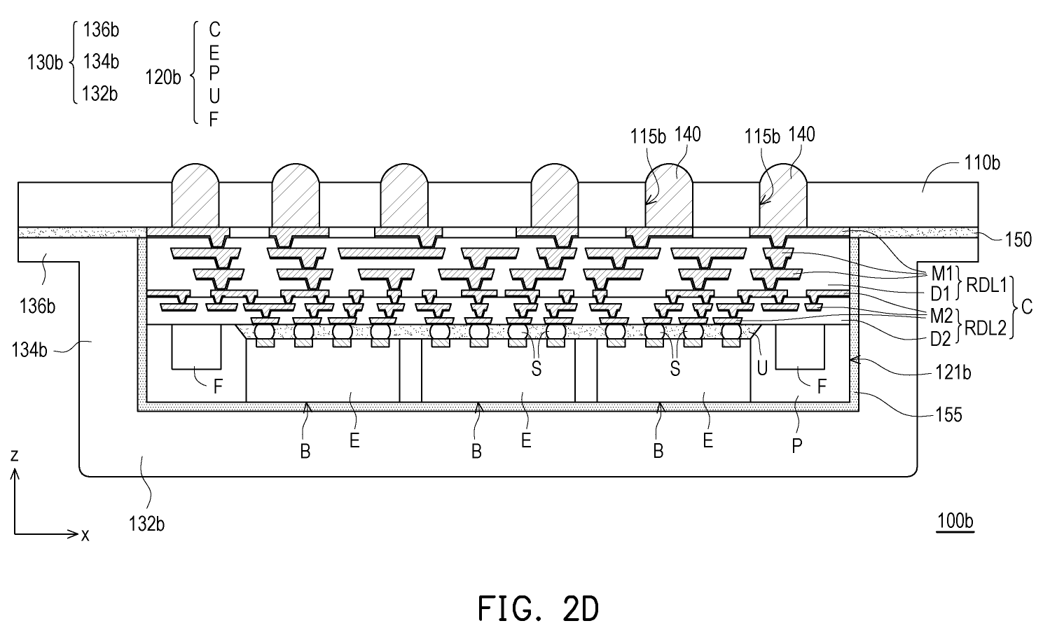

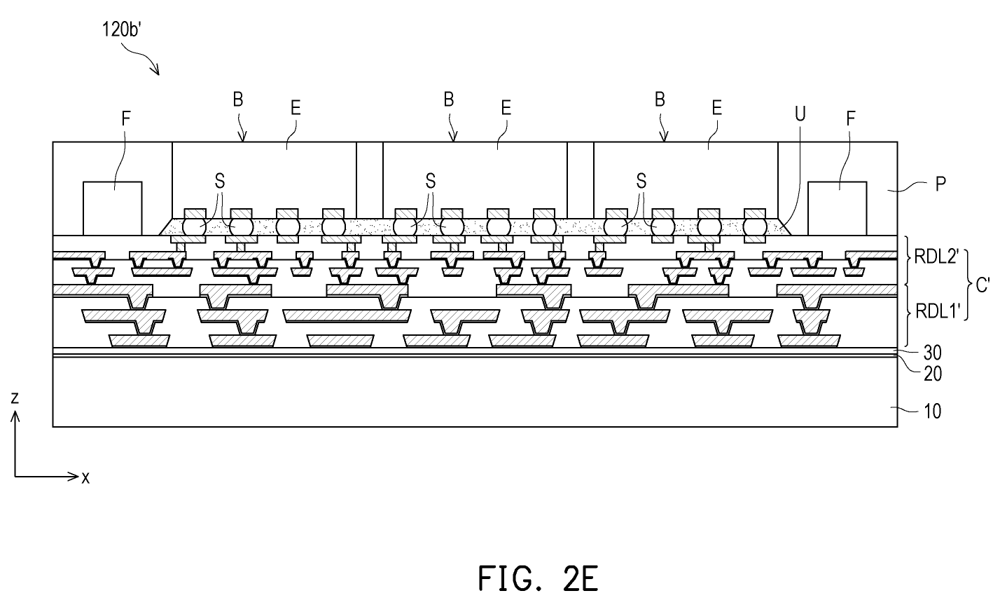

FIG. 2A to FIG. 2D are cross-sectional schematic diagrams of a manufacturing method of an electronic device according to an embodiment of the present disclosure. FIG. 2E is a cross-sectional schematic diagram of a manufacturing method of an electronic device according to another embodiment of the present disclosure. Please first refer to FIG. 2A. Regarding the manufacturing method of the electronic device of this embodiment, first, a temporary substrate 10, a stress adjustment layer 20, and a release film layer 30 are provided, wherein the stress adjustment layer 20 is located between the temporary substrate 10 and the release film layer 30. In one embodiment, the temporary substrate 10 is, for example, glass. In one embodiment, the stress adjustment layer 20 is an intermediate layer for balancing stress generated by different materials to forcibly resist warpage. Next, a circuit structure C is formed on the temporary substrate 10. The circuit structure C includes a second RDL RDL2 and a first RDL RDL1 located on the second RDL RDL2. The second RDL RDL2 directly contacts the release film layer 30 and includes a second metal layer M2 and a second dielectric layer D2, while the first RDL RDL1 includes a first metal layer M1 and a first dielectric layer D1. In one embodiment, the first RDL RDLb is, for example, a coarse-pitch RDL, while the second RLD RDL2 is, for example, a fine-pitch RDL . It should be noted that the number of layers of the first metal layer M1 and the number of layers of the second metal layer M2 may be increased or decreased according to requirements. In one embodiment, the first metal layer M1 and the second metal layer M2 may respectively be, for example, copper, wherein the CTE of copper is 15*10⁻⁶/K to 20*10⁻⁶/K, and the TC of copper is 350 W/m*K to 450W/m*K.

After the circuit structure C is completed, electrical testing is performed. It should be noted that during the manufacturing process of the above-mentioned circuit structure C, optical detection is used to determine whether there are defects. In one embodiment, optical microscopy (OM), X-ray, thin film thickness profiler (α-step), Automate Optical Inspection (AOI), or other suitable methods may be used to measure the area, width, thickness or height of each component, or the distance or pitch between components.

Next, please refer to FIG. 2A and FIG. 2B simultaneously, the structure of FIG. 2A is flipped upside down and attached to the temporary substrate 40, and the temporary substrate 10, stress adjustment layer 20, and release film layer 30 are removed to expose the second RDL RDL2. The temporary substrate 40 is disposed with a stress adjustment layer 50 and a release film layer 60, wherein the stress adjustment layer 50 is located between the temporary substrate 40 and the release film layer 60. The first RDL RDL1 directly contacts the release film layer 60. Next, the electronic unit E is electrically connected to the second metal layer M2 of the circuit structure C through the connecting component S. In one embodiment, the connecting component S is, for example, a solder ball with a diameter of 25 micrometers to 100 micrometers. Next, an annular dam F is set on the circuit structure C and surrounds the electronic unit E. Next, an adhesive layer U is provided between the electronic unit E and the circuit structure C, wherein the annular dam F has a blocking function to avoid adhesive overflow. Next, an encapsulant P is formed on the circuit structure C and covers the electronic unit E, the annular dam F, and the adhesive layer U, wherein a portion of the encapsulant P fills between adjacent electronic units E. Next, a grinding process is performed to remove a portion of the encapsulant P to expose the back surface B of the electronic unit E, which may effectively increase the heat dissipation effect. At this point, the fabrication of the package structure 120b is completed.

Afterward, please refer to FIG. 2B and FIG. 2C simultaneously, the structure of FIG. 2B is flipped upside down, and the package structure 120b is assembled into the heat dissipation cover 130b through the thermal interface material 155. The heat dissipation cover 130b includes an upper cover portion 132b, a side cover portion 134b, and an extension portion 136b. The upper cover portion 132b is attached to the back surface B of the electronic unit E through the thermal interface material 155. The side cover portion 134b connects the upper cover portion 132b and the extension portion 136b, and covers the peripheral surface 121b of the package structure 120b. In one embodiment, the extension direction of the upper cover portion 132b is parallel to the extension direction of the extension portion 136b, while the extension direction of the side cover portion 134b is perpendicular to the extension direction of the upper cover portion 132b. In one embodiment, the upper cover portion 132b, the side cover portion 134b, and the extension portion 136b are integrally formed structures. In one embodiment, the shape of the heat dissipation cover 130b is, for example, cap-shaped. In one embodiment, the material of the heat dissipation cover 130b is, for example, metal (such as copper, aluminum), alloy, diamond, or ceramic. In one embodiment, the material of the heat dissipation cover 130b is, for example, a metal material with high thermal conductivity, such as copper. The thermal interface material 155 is disposed between the electronic unit E and the upper cover portion 132b of the heat dissipation cover 130b, and between the side cover portion 134b of the heat dissipation cover 130b and the peripheral surface 121b of the package structure 120b, wherein the package structure 120b contacts the heat dissipation cover 130b through the thermal interface material 155. In one embodiment, the second metal layer M2 may directly contact the thermal interface material 155. Subsequently, the temporary substrate 40, the stress adjustment layer 50, and the release film layer 60 are removed to expose the first RDL RDL1 of the package structure 120b. Next, the heat dissipation component 110b having the through hole 115b is attached to the heat dissipation cover 130b and the first RDL RDL1 through the thermal interface material 150. At this time, the thermal interface material 150 is located between the extension portion 136b of the heat dissipation cover 130b and the heat dissipation component 110b. In one embodiment, the first metal layer M1 directly contacts the thermal interface material 150 and/or the thermal interface material 155. In one embodiment, the material of the heat dissipation component 110b is diamond, meaning the heat dissipation component 110b is an insulation support.

Finally, please refer to FIG. 2D, connecting components 140 are formed in the through holes 115b of the heat dissipation component 110b and extend outside the heat dissipation component 110b and electrically connect to the circuit structure C. The connecting components 140 of this embodiment directly contact the first metal layer M1 of the circuit structure C, fill the through holes 115b, and pass through the through holes 115b to extend outside the heat dissipation component 110b. In one embodiment, the aperture of the through holes 115b is approximately the same as the diameter of the connecting components 140. In one embodiment, the connecting components 140 are, for example, solder balls. At this point, the fabrication of the electronic device 100b is completed.

In another embodiment, please refer to FIG. 2E, a coarse-pitch first RDL RDL1' may also be first formed on the temporary substrate 10, and then a fine-pitch second RDL RDL2' is formed on the first RDL RDL1' to complete the fabrication of the circuit structure C'. Subsequently, the electronic unit E is electrically connected to the circuit structure C' through the connecting component S. The remaining process steps may refer to the aforementioned. After performing a grinding process to remove a portion of the encapsulant P, the back surface B of the electronic unit E is exposed, which may effectively increase the heat dissipation effect. At this point, the fabrication of the package structure 120b' is completed.

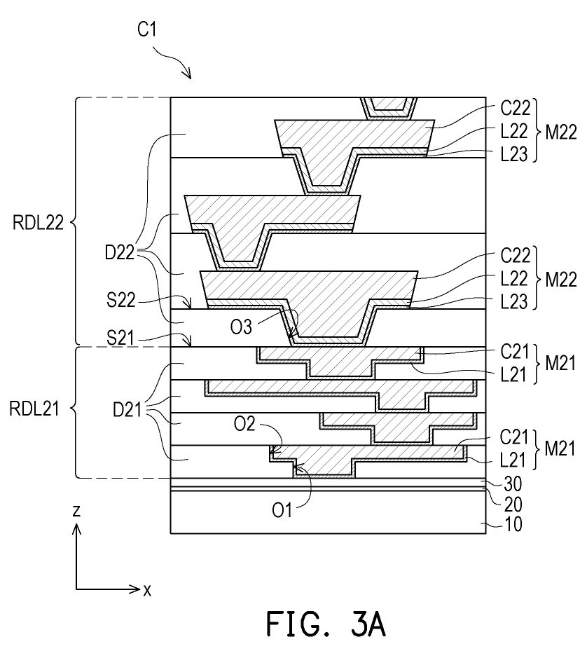

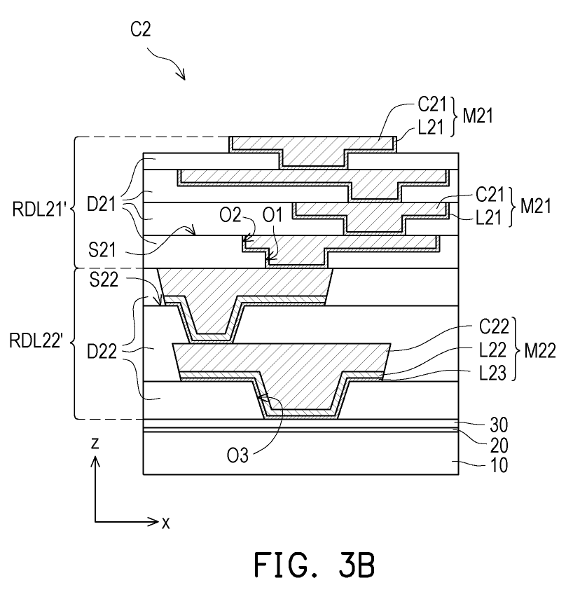

FIG. 3A is a partial cross-sectional schematic diagram of a circuit structure of an electronic device according to an embodiment of the present disclosure. Please refer to FIG. 2A and FIG. 3A simultaneously, the circuit structure C1 of this embodiment is similar to the circuit structure C of FIG. 2A, and the difference between them is that: in this embodiment, the second RDL RDL21 (i.e., the fine pitch RDL) of the circuit structure C1 includes alternately stacked second dielectric layers D21 and second metal layers M21, wherein the second metal layers M21 and the second dielectric layers D21 have surfaces that are substantially coplanar. In detail, the second RDL RDL21 is formed on the temporary substrate 10, wherein the stress adjustment layer 20 is located between the temporary substrate 10 and the release film layer 30, and the second RDL RDL21 is directly formed on the release film layer 30. In one embodiment, the temporary substrate 10 is, for example, a glass substrate.

In detail, the second dielectric layer D21 is formed on the temporary substrate 10 by a plasma chemical vapor deposition process. Herein, the material of the second dielectric layer D21 is, for example, an inorganic material. In one embodiment, the material of the second dielectric layer D21 is, for example, an organic material. It should be noted that the inorganic material needs to be formed on a surface with better flatness, such as the temporary substrate 10. Next, a photoresist layer is formed on the second dielectric layer D21, wherein the photoresist layer completely covers the top surface S21 of the second dielectric layer D21. Next, for example, a first photolithography process may be performed on the photoresist layer to form a first photoresist opening, wherein the first photoresist opening exposes a portion of the top surface S21 of the second dielectric layer D21. Next, a first reactive ion etching (RIE) process is performed on the second dielectric layer D21 to form a dielectric opening. At this time, the dielectric opening does not penetrate through the second dielectric layer D21, and the aperture of the dielectric opening is equal to the aperture of the first photoresist opening. Next, the above steps are repeated to form the second dielectric opening O2. Herein, the first dielectric opening O1 and the second dielectric opening O2 are connected to each other, and the aperture of the second dielectric opening O2 is larger than the aperture of the first dielectric opening O1. The first dielectric opening O1 is located between the second dielectric opening O2 and the temporary substrate 10, and the first dielectric opening O1 and the second dielectric opening O2 form a stepped structure. Next, the photoresist layer is removed to expose the top surface S21 of the second dielectric layer D21. Next, a seed material is formed on the top surface S21 of the second dielectric layer D21, on the inner wall of the first dielectric opening O1, and on the inner wall of the second dielectric opening O2. Next, a conductive material is formed on the seed material, wherein the conductive material covers the seed material and fills the first dielectric opening O1 and the second dielectric opening O2. Thereafter, a polishing process is performed on the conductive material and the seed material to expose the top surface S21 of the second dielectric layer D21, and form the conductive layer C21 and the seed layer L21 located within the first dielectric opening O1 and the second dielectric opening O2. Herein, the conductive layer C21 and the seed layer L21 define one layer of the second metal layer M21. The top surface S21 of the second dielectric layer D21 may be flush with the surface of the second metal layer M21. Next, optionally, the above steps may be repeated to form multiple layers of the second dielectric layer D21 and multiple layers of the second metal layer M21. Herein, the second metal layer M21 is formed through a dual damascene fabrication process plus a polishing process, which may have better flatness, wherein the second metal layer M21 has a stepped structure, and the second metal layer M21 has a metal line width and line spacing of less than, for example, 2 micrometers.

Next, please refer to FIG. 3A again, the first RDL RDL22 (i.e., coarse pitch RDL) of the circuit structure C1 includes alternately stacked first dielectric layers D22 and first metal layers M22 on the surface of the second dielectric layer D21 farthest from the temporary substrate 10. The first dielectric layer D22 has a top surface S22 and a dielectric opening O3, wherein the first metal layer M22 is located within the dielectric opening O3 of the first dielectric layer D22 and extends onto the top surface S22 to increase bonding strength. The first metal layer M22 includes a titanium layer L23, a copper layer L22, and a conductive layer C22, wherein the copper layer L22 is located between the titanium layer L23 and the conductive layer C22. Herein, the conductive layer C22 is, for example, copper. The formation method of the first dielectric layer D22 and the first metal layer M22 includes forming the first dielectric layer D22, performing exposure, development and baking on the first dielectric layer D22, forming a seed layer, forming a photoresist layer, performing exposure and development on the photoresist layer and using oxygen plasma to remove photoresist residues, electroplating the conductive layer, removing the photoresist layer and etching the seed layer. Optionally, the above steps may be repeated to form multiple layers of the first dielectric layer D22 and multiple layers of the first metal layer M22. At this point, the hybrid circuit structure C1 having organic material and inorganic material has been completed. Next, through a flip process and removing the carrier substrate 10, the electronic component may be bonded on the fine pitch second metal layer M21.

FIG. 3B is a partial cross-sectional schematic diagram of a circuit structure of an electronic device according to another embodiment of the present disclosure. Please refer to FIG. 3A and FIG. 3B simultaneously, the circuit structure C2 of this embodiment is similar to the circuit structure C1 of FIG. 3A, and the difference between them is that: in this embodiment, the coarse pitch first RDL RDL22' may be formed first on the temporary substrate 10, and then the fine pitch second RDL RDL21' is formed, wherein the second metal layer M21 for bonding the electronic component may protrude from the surface of the second dielectric layer D21, thereby enhancing the bonding strength with the electronic component.

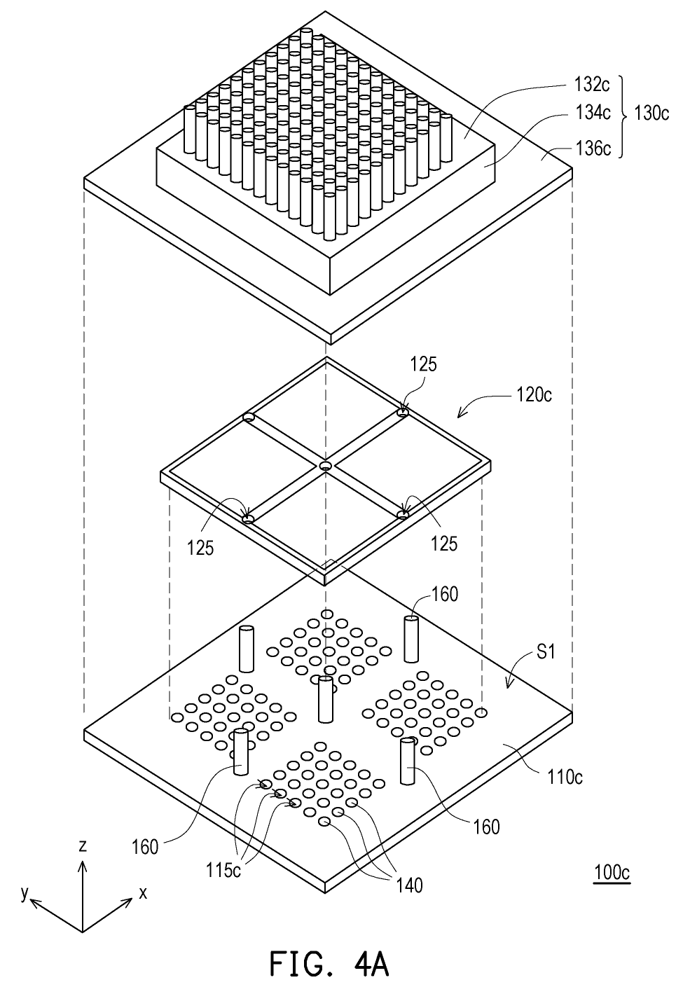

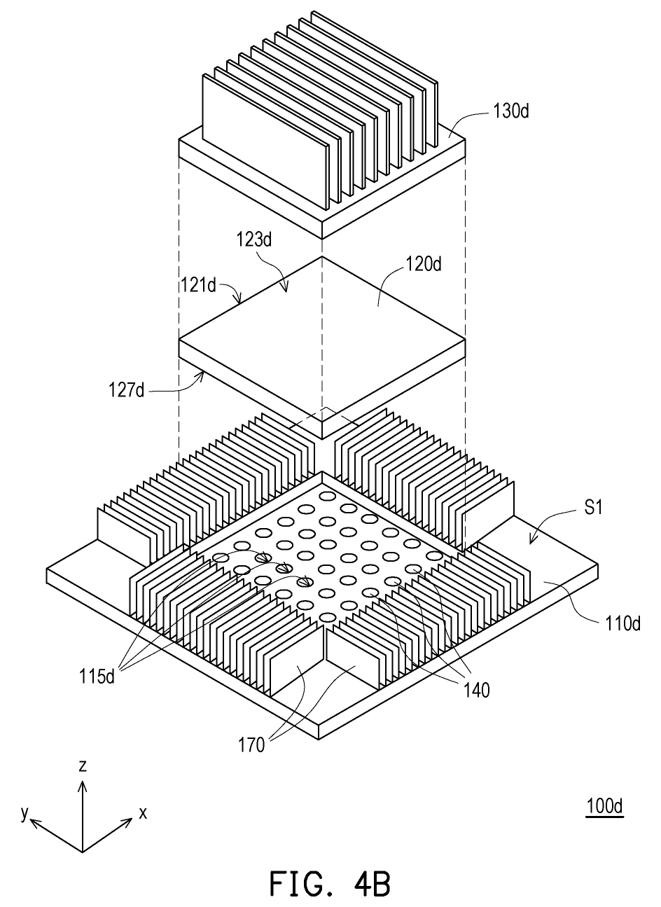

FIG. 4A is a perspective exploded schematic diagram of an electronic device according to an embodiment of the present disclosure. Please refer to FIG. 1 and FIG. 4A simultaneously, the electronic device 100c of this embodiment is similar to the electronic device 100a of FIG. 1, and the difference between them is that: in this embodiment, the electronic device 100c further includes a fixture 160, disposed on the first surface S1 of the heat dissipation component 110c. The package structure 120c includes a fixing hole 125, wherein the fixing hole 125 is a through hole penetrating through the package structure 120c, which is completed through mechanical drilling after the packaging process. In one embodiment, the fixing hole 125 is located in a non-chip active area of the package structure 120c, and the fixture 160 is positioned corresponding to the fixing hole 125. The heat dissipation cover 130c may include a heat dissipation fin portion 132c, a side cover portion 134c, and an extension portion 136c, wherein the side cover portion 134a vertically connects the heat dissipation fin portion 132a and the extension portion 136a. In one embodiment, the heat dissipation fin portion 132c of the heat dissipation cover 130c may have a fixing hole, disposed corresponding to the fixture 160. The fixture 160 on the heat dissipation component 110c passes through the fixing hole 125 of the package structure 120c and is fixed in the fixing hole of the heat dissipation fin portion 132c of the heat dissipation cover 130c, thereby attaching the heat dissipation cover 130c to the heat dissipation component 110c. In one embodiment, the fixture 160 is, for example, a bolt, wherein the material of the fixture 160 is, for example, a material that easily conducts heat and has a small CTE. Since the heat dissipation component 110c of the electronic device 100c of this embodiment has the design of the fixture 160, in addition to assisting the package structure 120c in heat dissipation, it may also simultaneously strengthen the fixation with the heat dissipation cover 130c and the package structure 120c, achieving the effect of enhancing overall structural rigidity. In addition, the heat dissipation component 110c having the through hole 115c may support the connecting component 140, and may prevent the edge of the connecting component 140 from fracturing due to stress.

FIG. 4B is a perspective exploded schematic diagram of an electronic device according to another embodiment of the present disclosure. Please refer to FIG. 1 and FIG. 4B simultaneously, the electronic device 100d of this embodiment is similar to the electronic device 100a of FIG. 1, and the difference between them is that: in this embodiment, the electronic device 100d further includes a plurality of heat dissipation fins 170, dispersedly disposed on the first surface S1 of the heat dissipation component 110d. Herein, the plurality of heat dissipation fins 170 are arranged on the first surface S1 of the heat dissipation component 110d to surround and form an annular dam with a certain height, so that the heat dissipation cover 130d having heat dissipation fins is attached to the package structure 120d. In brief, the bottom portion 127d of the package structure 120d is covered with the heat dissipation component 110d having the through hole 115d, and the top portion 123d and the peripheral surface 121d of the package structure 120d are surrounded by the a plurality of heat dissipation fins 170 to form a six-sided supporting and heat dissipation structure, which may have better heat dissipation effect or may improve thermal deformation. In one embodiment, the height of the plurality of heat dissipation fins 170 is greater than the thickness of the package structure 120d.

Finally, it should be noted that the above embodiments are only used to illustrate, but not to limit, the technical solutions of the disclosure. Although the disclosure has been described in detail with reference to the above embodiments, persons skilled in the art should understand that the technical solutions described in the above embodiments may still be modified or some or all of the technical features thereof may be equivalently replaced. However, the modifications or replacements do not cause the essence of the corresponding technical solutions to deviate from the scope of the technical solutions of the embodiments of the disclosure.

What is claimed is:

1. An electronic device, comprising:
a heat dissipation component having a first surface and a second surface opposite to each other;
a through hole penetrating through the heat dissipation component;
a package structure disposed on the first surface of the heat dissipation component and comprising a circuit structure and an electronic unit, the circuit structure comprising a metal layer, and the heat dissipation component having a thermal conductivity different from a thermal conductivity of the metal layer, the electronic unit disposed on the circuit structure and is electrically connected to the circuit structure;
a heat dissipation cover attached to the package structure; and
a connecting component electrically connected to the circuit structure of the package structure and extending through the through hole of the heat dissipation component beyond the second surface of the heat dissipation component.

2. The electronic device as described in claim 1, wherein the heat dissipation cover comprises a heat dissipation fin portion, a side cover portion, and an extension portion, the heat dissipation fin portion attached to the electronic unit, the side cover portion connecting the heat dissipation fin portion and the extension portion and covering a peripheral surface of the package structure, and the extension portion attached to the heat dissipation component.

3. The electronic device as described in claim 2, further comprising:
a thermal interface material disposed between the heat dissipation component and the extension portion of the heat dissipation cover.

4. The electronic device as described in claim 2, further comprising:
a thermal interface material disposed between the electronic unit and the heat dissipation fin portion of the heat dissipation cover and between the side cover portion of the heat dissipation cover and the peripheral surface of the package structure.

5. The electronic device as described in claim 2, further comprising:
a fixture disposed on the first surface of the heat dissipation component, the package structure comprising a fixing hole, the fixture extending through the fixing hole and fixed to the heat dissipation fin portion of the heat dissipation cover, thereby attaching the heat dissipation cover to the heat dissipation component.

6. The electronic device as described in claim 1, further comprising:
a plurality of heat dissipation fins dispersedly disposed on the first surface of the heat dissipation component, the plurality of heat dissipation fins surrounding a peripheral surface of the package structure.

7. The electronic device as described in claim 6, wherein a height of the plurality of heat dissipation fins is greater than a thickness of the package structure.

8. The electronic device as described in claim 1, wherein the metal layer of the circuit structure comprises a first metal layer and a second metal layer, the first metal layer located between the second metal layer and the heat dissipation component, and a line width and line spacing of the first metal layer being greater than a line width and line spacing of the second metal layer.

9. The electronic device as described in claim 1, wherein the heat dissipation component comprises a conductive portion and an insulation portion, the insulation portion covering the conductive portion.

10. The electronic device as described in claim 9, wherein a material of the conductive portion comprises Invar alloy, and a material of the insulation portion comprises silicon oxide, silicon nitride, aluminum nitride, silicon carbide, aluminum silicon carbide, or diamond.

11. The electronic device as described in claim 1, wherein a thickness of the heat dissipation component is between 100 micrometers and 2000 micrometers.

12. The electronic device as described in claim 1, wherein a material of the heat dissipation cover comprises metal, alloy, or diamond.

13. The electronic device as described in claim 1, wherein the package structure further comprises an encapsulant disposed on the circuit structure and covering the electronic unit.

14. The electronic device as described in claim 1, wherein a dimension of the heat dissipation component is greater than a dimension of the package structure.

15. The electronic device as described in claim 1, wherein a material of the heat dissipation component comprises aluminum nitride, silicon carbide, or diamond.

16. The electronic device as described in claim 1, wherein the metal layer of the circuit structure of the package structure comprises a first metal layer and a second metal layer, the first metal layer located between the second metal layer and the heat dissipation component.

17. The electronic device as described in claim 16, wherein the circuit structure of the package structure further comprises a first dielectric layer and a second dielectric layer, the first metal layer and the first dielectric layer defining a first redistribution layer, and the second metal layer and the second dielectric layer defining a second redistribution layer.

18. The electronic device as described in claim 1, wherein the package structure further comprises an adhesive layer disposed between the electronic unit and the circuit structure.

19. The electronic device as described in claim 18, wherein the package structure further comprises an encapsulant disposed on the circuit structure and covering the electronic unit and the adhesive layer, wherein the encapsulant exposes a back surface of the electronic unit.

20. The electronic device as described in claim 1, wherein the electronic unit comprises passive components, active components, or a combination thereof.
